(19) United States
(12) Patent Application Publication
(10) Pub. No.: US 2006/0192594 A1
(43) Pub. Date: Aug. 31, 2006

(54) Linear phase detector with multiplexed latches

(76) Inventor: Mihai Adrian Tiberiu Sanduleanu, EINDHOVEN (NL)

Correspondence Address: PHILIPS INTELLECTUAL PROPERTY & STANDARDS, P.O. BOX 3001, BRIARCLIFF MANOR, NY, 10510, US

(21) Appl. No.: 10/550,354

(22) PCT Filed: Mar. 23, 2004
(86) PCT No.: PCT/IB04/50316

§ 371 Date: Sep. 23, 2005

(30) Foreign Application Priority Data
Mar. 28, 2003 (EP) 03100829.5

(51) Int. Cl. H03K 9/06

(52) U.S. Cl. 327/47

(57) ABSTRACT

Linear phase detectors comprising circuits (1,2) receiving first and second clock signals (CLKOO, CLK90) for generating first and second control signals (UP,DOWN) for use in clock extractors and data regenerators have large delays due to long path lengths and many operations between input and output (insight). They can be made faster by providing each circuit (1,2) with two parallel latches (10,11,20,21) and a multiplexer (12,22) for multiplexing latch output signals (basic idea). A data signal is supplied to the first circuit (1), and a first circuit output signal is supplied to the second circuit (2). By introducing a third and a fourth circuit (3,4) each also comprising two latches and a multiplexer, a fast linear phase detector has been constructed having a gain which is independent from the number of transitions in the data signal, which is advantageous. Logical circuitry (13,23) of each circuit (1,2,3,4) is coupled to an adder/subtracter (5).

The invention relates to a linear phase detector comprising at least a first circuit receiving at least one first clock signal for generating at least one first control signal and at least a second circuit receiving at least one second clock signal for generating at least one second control signal.

The invention also relates to a clock extractor and data regenerator comprising such a linear phase detector, and to a method for linearly phase detecting, and to a processor program product for linearly phase detecting, and to an apparatus comprising such a clock extractor and data regenerator.

Such a linear phase detector is for example used in clock extractors and data regenerators of an open loop configuration or a closed loop configuration (like for example a Phase Locked Loop) and can for example be found in optical receivers. Said linear phase detector controls the phase of a clock (like for example a controlled oscillator) which needs to be synchronized with the incoming data. Thereto, said first control signal for example comprises an up signal or comprises an error signal, and said second control signal for example comprises a down signal or comprises a reference signal etc.

Such a clock extractor and data regenerator for example comprises said linear phase detector receiving data (at for example a data input) and followed by a filter, a controlled oscillator and a frequency divider fed back to (for example a clock input of) said linear phase detector. Said apparatus for example comprises an optical receiver for receiving an optical signal and comprising a converter for converting said optical signal into an electrical signal and comprising said clock extractor and data regenerator for extracting a clock signal and for regenerating a data signal from said electrical signal.

A prior art linear phase detector is known from U.S. Pat. No. 5,712,580, which discloses a linear phase detector generating an up signal via a first D-flip-flop receiving an input signal from a second D-flip-flop situated in a feedback loop and generating a down signal via a third D-flip-flop receiving an input signal from said first D-flip-flop, based upon quadrature clock signals.

The known linear phase detector is disadvantageous, inter alia, due to being slow: said feedback loop, said D-flip-flops each comprising two latches and the triple D-flip-flop construction necessary for generating said down signal make this linear phase detector unsuitable for operating a higher frequencies.

It is an object of the invention, inter alia, of providing a faster linear phase detector suitable for operation at higher frequencies.

Further objects of the invention are, inter alia, providing a faster clock extractor and data regenerator, a faster method, a faster processor program product, and a faster apparatus.

The linear phase detector according to the invention comprises at least a first circuit receiving at least one first clock signal for generating at least one first control signal and at least a second circuit receiving at least one second clock signal for generating at least one second control signal, wherein each one of said circuits comprises at least two latches and at least one multiplexer for multiplexing latch output signals.

By providing the linear phase detector according to the invention with parallel latches and multiplexers for multiplexing latch output signals, each pair of parallel latches will operate substantially simultaneously, with the multiplexer multiplexing the results from these operations. As a result, the delay from inputs of a pair of latches in the first circuit to an output of a multiplexer of the second circuit is reduced, which makes the linear phase detector faster.

It should be noted that each pair of parallel latches is defined to be parallel due to operating substantially simultaneously (substantially, due to possible different path lengths, different parasitic capacitors etc.) because of both receiving at least one same input signal (a data signal or a clock signal etc.) and/or because of both latches supplying their outputs signals to the same multiplexer. So, said pair of latches receive at least one same input signal and/or supply their output signals to the same multiplexer. Said latches are, in other words, multiplexed latches.

A first embodiment of the linear phase detector according to the invention is defined by claim 2.

By supplying the data signal to the first latches of said first circuit and supplying the first multiplexer output signal to the second latches of said second circuit, the linear phase detector can be constructed efficiently in semiconductor technology.

A second embodiment of the linear phase detector according to the invention is defined by claim 3.

By introducing said first logical circuitry and said second logical circuitry, like for example EXOR gates, a low cost, low complex and low power consuming, linear phase detector has been constructed.

It should further be noted that prior art non-linear phase detectors exist comprising multiplexed parallel latches. However, firstly, said prior art phase detectors are non-linear phase detectors, and secondly, in said non-linear prior art phase detectors both circuits are not coupled serially (with serially coupled meaning that the data signal is supplied to the first circuit and that the output signal of the first signal is supplied—as data signal—to the second circuit etc.).

A third embodiment of the linear phase detector according to the invention is defined by claim 4.

By introducing said third circuit and said fourth circuit, a fast linear phase detector has been constructed of which the combined result of the control signals after low pass filtering has become independent of the number of data transitions in the data signal. In other words, said combined result will, after low pass filtering, have an average value equal to zero, and the gain of the linear phase detector has become independent from the number of transitions in the data signal, which independency is advantageous.

A fourth embodiment of the linear phase detector according to the invention is defined by claim 5.

By supplying the second circuit output signal or the second multiplexer output signal to the third latches and supplying the third multiplexer output signal to the fourth latches, the linear phase detector having a data transition independent gain can be constructed efficiently in semiconductor technology.

A fifth embodiment of the linear phase detector according to the invention is defined by claim 6.

By introducing said third logical circuitry and said fourth logical circuitry, like for example EXOR gates, a low cost, low complex and low power consuming, linear phase detector having a data transition independent gain has been constructed.

A sixth embodiment of the linear phase detector according to the invention is defined by claim 7.

By coupling each one of said logical circuitry to an adder/subtracter, the combined result from this adder/subtracter (for example adding the first and fourth control signal and subtracting the second and third control signal) can be supplied to a charge pump and/or to a low pass filter.

Embodiments of the clock extractor and data regenerator according to the invention, of the method according to the invention, of the processor program product according to the invention and of the apparatus according to the invention correspond with the embodiments of the linear phase detector according to the invention.

The invention is based upon an insight, inter alia, that, generally, delay depends upon path lengths present between input to output and upon the number of operations performed between input and output, and is based upon a basic idea, inter alia, that, in a linear phase detector, a pair of parallel latches plus multiplexer per circuit will minimize this delay (minimum path length and minimum number of operations).

The invention solves the problem, inter alia, of providing a faster linear phase detector, and is advantageous, inter alia, in that such a faster linear phase detector can operate at higher frequencies (like for example at a frequency twice as high etc. compared to prior art detectors when using the same technology), whereby said linear phase detector can be further improved by introducing a data transition independent gain.

These and other aspects of the invention will be apparent from and elucidated with reference to the embodiments(s) described hereinafter.

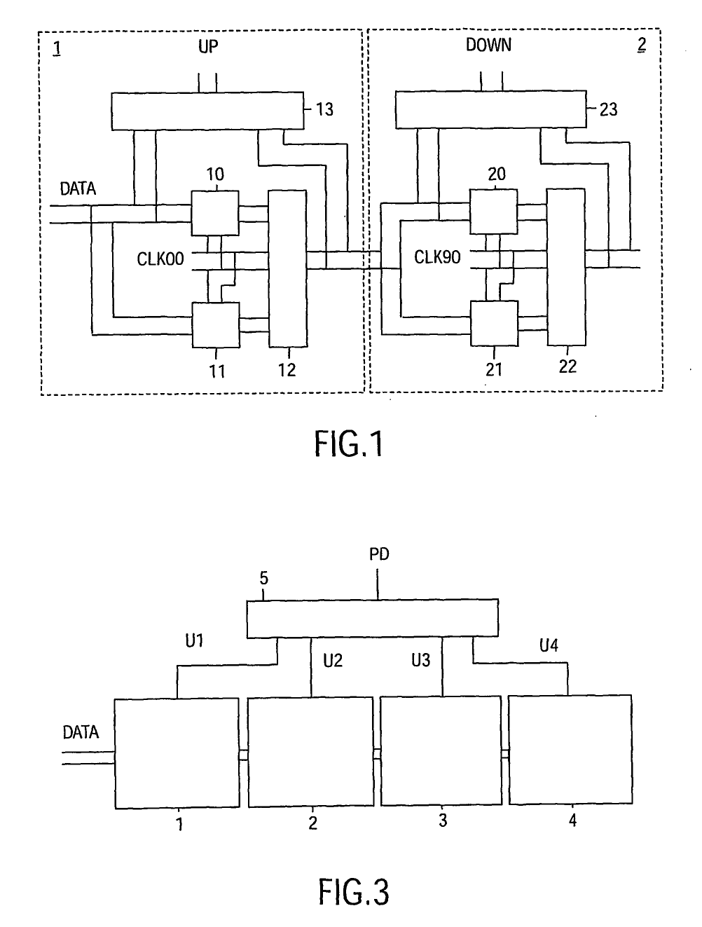

FIG. 1 illustrates in block diagram form a linear phase detector according to the invention comprising two circuits,

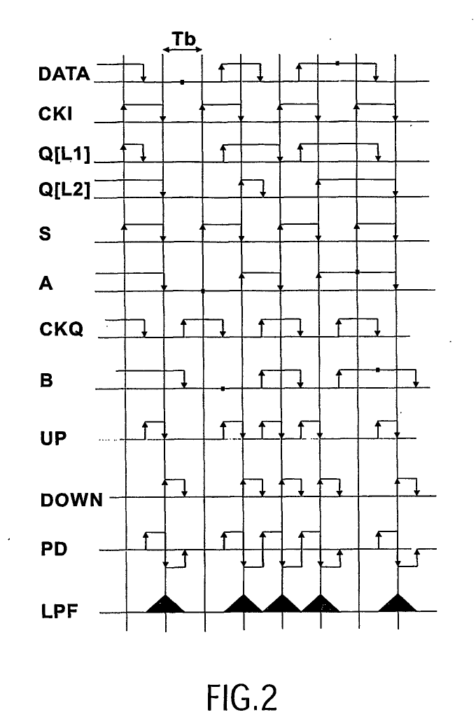

FIG. 2 illustrates in block diagram form a timing diagram for said linear phase detector comprising two circuits,

FIG. 3 illustrates in block diagram form a linear phase detector according to the invention comprising four circuits, and

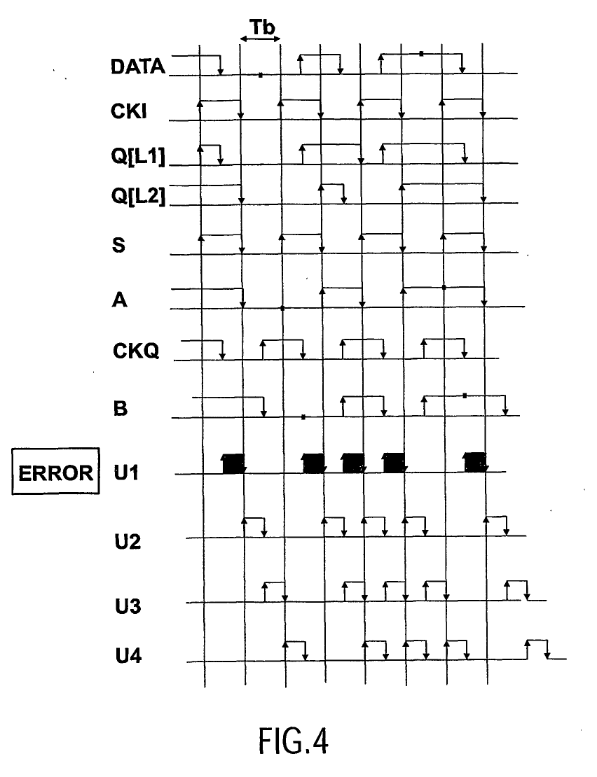

FIG. 4 illustrates in block diagram form a timing diagram for said linear phase detector comprising four circuits.

The linear phase detector according to the invention shown in FIG. 1 comprises a first circuit 1 with a latch 10 receiving at its data inputs (with the upper being the normal data input and with the lower being the inverted data input) the data signals and receiving at its respective clock inputs (with the left clock input being the normal clock input and with the right clock input being the inverted clock input) the clock signals at 00 degrees (first clock signal). A normal output (the upper output) of latch 10 is coupled to a first normal input of a multiplexer 12, and an inverted output (the lower output) of latch 10 is coupled to a first inverted input of multiplexer 12.

Circuit 1 further comprises a latch 11 receiving at its data inputs (with the upper being the normal data input and with the lower being the inverted data input) the data signals and receiving at its respective clock inputs (with the left clock input being the normal clock input and with the right clock input being the inverted clock input) the clock signals at 00 degrees via, compared to latch 10, exchanged connections. A normal output (the lower output) of latch 11 is coupled to a second inverted input of multiplexer 12, and an inverted output (the higher output) of latch 11 is coupled to a second normal input of multiplexer 12.

Multiplexer 12 receives at its control inputs (with the upper being the normal control input and with the lower being the inverted control input) said clock signals at 00 degrees via, compared to latch 10, non-exchanged connections.

Circuit 1 further comprises logical circuitry 13 like for example an EXOR gate receiving said data signals and the multiplexer output signals for generating a first control signal (UP signal).

The linear phase detector according to the invention shown in FIG. 1 further comprises a second circuit 2 with a latch 20 receiving at its data inputs (with the upper being the normal data input and with the lower being the inverted data input) the multiplexer output signals from the outputs of multiplexer 12 (with the upper being the normal output and with the lower being the inverted output) via non-exchanged connections and receiving at its respective clock inputs (with the left clock input being the normal clock input and with the right clock input being the inverted clock input) the clock signals at 90 degrees (second clock signal). A normal output (the upper output) of latch 20 is coupled to a first normal input of a multiplexer 22, and an inverted output (the lower output) of latch 20 is coupled to a first inverted input of multiplexer 22.

Circuit 2 further comprises a latch 21 receiving at its data inputs (with the upper being the normal data input and with the lower being the inverted data input) the data signals and receiving at its respective clock inputs (with the left clock input being the normal clock input and with the right clock input being the inverted clock input) the clock signals at 90 degrees via, compared to latch 20, exchanged connections. A normal output (the lower output) of latch 21 is coupled to a second inverted input of multiplexer 22, and an inverted output (the higher output) of latch 21 is coupled to a second normal input of multiplexer 22.

Multiplexer 22 receives at its control inputs (with the upper being the normal control input and with the lower being the inverted control input) said clock signals at 90 degrees via, compared to latch 20, non-exchanged connections.

Circuit 2 further comprises logical circuitry 23 like for example an EXOR gate receiving said multiplexer output signals from the outputs of multiplexers 12 and 22 for generating a second control signal (DOWN signal).

The timing diagram of the linear phase detector illustrated in FIG. 1 is shown in FIG. 2, with CKI being the first clock signal at 00 degrees, with Q(L1) being the output signal of latch 10, with Q(L2) being the output signal of latch 11, with S being the control input signal of multiplexer 12, with A indicating the output signal of multiplexer 12, with CKQ being the second clock signal at 90 degrees, with B indicating the output signal of multiplexer 22, with UP being the output signal of circuitry 13, with DOWN being the output signal of circuitry 23, with PD indicating the linear phase detector signal generated through combining said UP signal and said DOWN signal, and with LPF indicating said PD signal after being low pass filtered.

Due to LPF having an average value unequal to zero, said linear phase detector comprising two circuits 1,2 as illustrated in FIG. 1 will not have a gain which is independent from the number of transitions in the data signal.

The linear phase detector according to the invention shown in FIG. 3 comprises four circuits 1, 2, 3 and 4, with circuits 1 and 2 corresponding with those shown in FIG. 1 and with the respective circuits 3 and 4 being equally built (and comprising the respective latches 30,31 and 40,41 and the respective multiplexers 32 and 42 and the respective logical circuitries 33 and 43 all not shown) and receiving the respective first (at 00 degrees) and second (at 90 degrees) clock signals, and with circuit 3 further receiving the output signal of circuit 2 (more precisely the output signal of multiplexer 22) and with circuit 4 receiving the output signal of circuit 3 (more precisely the output signal of the multiplexer 32 not shown). Logical circuitries 13, 23, 33 and 43 generate four control signals U1 (used to be UP), U2 (used to be DOWN), U3 and U4, which are supplied to an adder/subtracter 5 which adds for example U1 and U4 and subtracts U2 and U3 and which generates the signal PD.

The timing diagram of the linear phase detector illustrated in FIG. 3 is shown in FIG. 4, with CKI being the first clock signal at 00 degrees, with Q(L1) being the output signal of latch 10, with Q(L2) being the output signal of latch 11, with S being the control input signal of multiplexer 12, with A indicating the output signal of multiplexer 12, with CKQ being the second clock signal at 90 degrees, with B indicating the output signal of multiplexer 22, with U1 being the output signal of circuitry 13, with U2 being the output signal of circuitry 23, with U3 being the output signal of circuitry 33 and with U4 being the output signal of circuitry 43.

The signal PD is not shown but can be constructed through calculating U1−U2−U3+U4 and indicates the linear phase detector signal generated through combining said U1, U2, U3 and U4. The signal LPF is not shown but can be constructed easily through integrating said PD signal (with integrating corresponding with low pass filtering). Due to LPF now having an average value equal to zero, said linear phase detector comprising four circuits 1,2,3,4 as illustrated in FIG. 3 will have a gain which is independent from the number of transitions in the data signal. This independency is very advantageous.

The phase detectors shown in FIGS. 1 and 3 have double connections to fulfil the so-called balanced situation. But the invention is not limited to this balanced situation and can be used in the so-called unbalanced situation as well, with single connections.

The expression “for” in “for K” and “for L” does not exclude that other functions “for M” etc. are performed as well, simultaneously or not. The expressions “X coupled to Y” and “a coupling between X and Y” and “coupling/couples X and Y” etc. do not exclude that an element Z is in between X and Y. The expressions “P comprises Q” and “comprising Q” etc. do not exclude that an element R is comprised/included as well.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

The invention is based upon an insight, inter alia, that, generally, delay depends upon path lengths present between input to output and upon the number of operations performed between input and output, and is based upon a basic idea, inter alia, that, in a linear phase detector, a pair of parallel latches plus multiplexer per circuit will minimize this delay (minimum path length and minimum number of operations).

The invention solves the problem, inter alia, of providing a faster linear phase detector, and is advantageous, inter alia, in that such a faster linear phase detector can operate at higher frequencies (like for example at a frequency twice as high etc. compared to prior art detectors when using the same technology), whereby said linear phase detector can be further improved by introducing a data transition independent gain.

1. Linear phase detector comprising at least a first circuit (1) receiving at least one first clock signal (CLK00) for generating at least one first control signal (UP,U1) and at least a second circuit (2) receiving at least one second clock signal (CLK90) for generating at least one second control signal (DOWN,U2), wherein each one of said circuits (1,2) comprises at least two latches (10,11,20,21) and at least one multiplexer (12,22) for multiplexing latch output signals.

2. Linear phase detector according to claim 1, wherein first latches (10,11) of said first circuit (1) receive at least one data signal (DATA), with a first multiplexer (12) of said first circuit (1) generating at least one first multiplexer output signal destined for second latches (20,21) of said second circuit (2).

3. Linear phase detector according to claim 2, wherein first logical circuitry (13) of said first circuit (1) receives said data signal (DATA) and said first multiplexer output signal for generating said first control signal (UP,U1), with second logical circuitry (23) of said second circuit (2) receiving said first multiplexer output signal and at least one second multiplexer output signal for generating said second control signal (DOWN,U2).

4. Linear phase detector according to claim 1, wherein said linear phase detector comprises at least a third circuit (3) receiving said first clock signal (CLK00) for generating at least one third control signal (U3) and at least a fourth circuit (4) receiving said second clock signal (CLK90) for generating at least one fourth control signal (U4), wherein each one of said circuits (3,4) comprises at least two latches and at least one multiplexer for multiplexing latch output signals.

5. Linear phase detector according to claim 4, wherein third latches of said third circuit (3) receive at least one second circuit output signal, with a third multiplexer of said third circuit (3) generating at least one third multiplexer output signal destined for fourth latches of said fourth circuit (4).

6. Linear phase detector according to claim 5, wherein third logical circuitry of said third circuit (3) receives said second circuit output signal and said third multiplexer output signal for generating said third control signal (U3), with fourth logical circuitry of said fourth circuit (4) receiving said third multiplexer output signal and at least one fourth multiplexer output signal.

7. Linear phase detector according to claim 6, wherein each one of said logical circuitry is coupled to an adder/subtracter (5).

8. Clock extractor and data regenerator comprising a linear phase detector with at least a first circuit (1) receiving at least one first clock signal (CLK00) for generating at least one first control signal (UP,U1) and at least a second circuit (2) receiving at least one second clock signal (CLK90) for generating at least one second control signal (DOWN,U2), wherein each one of said circuits (1,2) comprises at least two latches (10,11,20,21) and at least one multiplexer (12,22) for multiplexing latch output signals.

9. Method for linearly phase detecting and comprising a first step of receiving at least one first clock signal (CLK00) for generating at least one first control signal (UP,U1) and a second step of receiving at least one second clock signal (CLK90) for generating at least one second control signal (DOWN,U2), wherein said steps each comprise the substeps of latching and of multiplexing results from said latching.

10. Processor program product for linearly phase detecting and comprising a first function of receiving at least one first clock signal (CLK00) for generating at least one first control signal (UP,U1) and a second function of receiving at least one second clock signal (CLK90) for generating at least one second control signal (DOWN,U2), wherein said functions each comprise the subfunctions of latching and of multiplexing results from said latching.

11. Apparatus comprising a clock extractor and data regenerator comprising a linear phase detector with at least a first circuit (1) receiving at least one first clock signal (CLK00) for generating at least one first control signal (UP,U1) and at least a second circuit (2) receiving at least one second clock signal (CLK90) for generating at least one second control signal (DOWN,U2), wherein each one of said circuits (1,2) comprises at least two latches (10,11,20,21) and at least one multiplexer (12,22) for multiplexing latch output signals.
